(19) United States
(12) Patent Application Publication
(10) Pub. No.: US 2025/0022736 A1
(43) Pub. Date: Jan. 16, 2025

(54) SUBSTRATE TRANSPORT SYSTEM AND TRANSFER ROBOT CONTROL DEVICE

(71) Applicant: HIRATA CORPORATION, Kumamoto-shi (JP)

(72) Inventor: Itaru MOMOKI, Kumamoto-shi (JP)

(73) Assignee: HIRATA CORPORATION, Kumamoto-shi (JP)

(21) Appl. No.: 18/898,123

(22) Filed: Sep. 26, 2024

Related U.S. Application Data
(63) Continuation of application No. PCT/JP2023/013205, filed on Mar. 30, 2023.

(30) Foreign Application Priority Data
Mar. 30, 2022 (WO) PCT/JP2022/016231

(51) Int. Cl. H01L 21/677; B25J 9/04; B25J 9/10; B25J 11/00; H01L 21/67

(52) U.S. Cl. CPC H01L 21/67742; B25J 9/042; B25J 9/107; B25J 11/0095; H01L 21/67259

(57) ABSTRACT

A substrate transport system includes a transport section a first placement portion and a second placement portion, and a transfer robot, wherein the transfer robot includes a main body unit disposed inside a transfer section, a turning support unit connected to the main body unit, an arm support unit connected to the turning support unit, an arm unit connected to the arm support unit, and a holding unit connected to the arm unit, wherein the arm unit includes a first arm that is supported by the arm support unit and a second arm that supports the holding unit and is supported by the first arm, wherein the turning support unit rotates using a connection portion with the main body unit as a rotation shaft in a plan view, the arm support unit rotates using a connection portion with the turning support unit as a rotation shaft in a plan view.

This application is a continuation of International Application No. PCT/JP2023/013205 filed on Mar. 30, 2023, which claims priority to International Patent Application No. PCT/JP2022/016231 filed on Mar. 30, 2022, the contents of both of which are incorporated herein by reference.

### TECHNICAL FIELD

The present invention relates to a substrate transport system and a transfer robot control device.

### BACKGROUND ART

A substrate transport system in which a transfer robot that transports a semiconductor substrate (a wafer) is installed in a chamber (a clean room) in a vacuum environment and the wafer is transported from a load port attached to the front of the chamber is known. In the above-mentioned substrate transport system, the wafer taken into the chamber by the transfer robot is transported to the chamber or to a process module attached to the chamber, where various types of semiconductor treatment such as film formation treatment are performed. After being treated in the process module, the wafer is transported again to the load port by the transfer robot and sent to the next step.

For example, Patent Documents 1 to 3 disclose a substrate transport system in which a transfer robot is fixed in a chamber and a wafer is transported without the transfer robot running in the chamber, and thus the raising of particles or the disturbance of airflow does not occur in the chamber.

### RELATED ART DOCUMENT

### Patent Document

Patent Document 1: Japanese Unexamined Patent Application, First Publication No. 2011-119556
Patent Document 2: Japanese Patent No. 5199117
Patent Document 3: Japanese Patent No. 4746027

### SUMMARY

### Problems to be Solved by the Invention

In the above-mentioned substrate transport system, by making an interval between a robot that transports a wafer and a port to which a wafer is transported large, a space for an arm of the robot to turn is ensured, and thus the movement distance of a wafer is long to decrease and the efficiency of a transport operation decreases.

The present invention has been made in consideration of the above circumstances, and an object of the present invention is to provide a substrate transport system and a transfer robot control device that can efficiently transport a substrate.

### Means for Solving the Problem

According to the present invention, there is provided a substrate transport system including: a transport section that defines a range within which a substrate is transported; a first placement portion and a second placement portion on which the substrate is placed; and a transfer robot that is provided inside the transport section and transports the substrate from the first placement portion to the second placement portion, wherein the transfer robot includes a main body unit that is supported within the transport section, a turning support unit that is connected to the main body unit and rotates relative to the main body unit, an arm support unit that is connected to the turning support unit and rotates relative to the turning support unit, an arm unit that is connected to the arm support unit and rotates relative to the arm support unit, and a holding unit that is connected to the arm unit and holds the substrate, wherein the arm unit includes a first arm that is supported by the arm support unit, and a second arm that supports the holding unit and is supported by the first arm, wherein the turning support unit rotates using a connection portion with the main body unit as a rotation shaft in a plan view, wherein the arm support unit rotates using a connection portion with the turning support unit as a rotation shaft in a plan view, wherein the arm unit rotates using the arm support unit as a rotation shaft in a plan view, and wherein the holding unit rotates relative to the second arm using a portion supported by the first arm as a rotation shaft in a plan view.

In the substrate transport system according to the present invention, the transfer robot may include a turning motor that rotates the turning support unit relative to the main body unit, an arm support drive motor that rotates the arm support unit relative to the turning support unit, and an arm motor that rotates the arm unit relative to the arm support unit.

In the substrate transport system according to the present invention, the arm support unit may include an arm motor including an arm drive mechanism that operates the arm unit.

In the substrate transport system according to the present invention, the arm support unit may include a turning attachment portion that is connected to the turning support unit, and an arm attachment portion to which the arm unit is connected. A center line of rotation of the arm support unit relative to the turning support unit and a center line of rotation of the arm unit relative to the arm support unit may be set on the same line.

The substrate transport system according to the present invention may further include a robot control unit for controlling a transport operation of the substrate by the transfer robot. The robot control unit may control an operation of each of the arm support unit, the arm unit, and the holding unit such that, when transferring the substrate between a first placement position set on the first placement portion and a first pre-placement position set opposite to the first placement portion, the holding unit is moved while maintaining a posture of the holding unit that holds the substrate in a predetermined direction along a center line connecting the first placement position and the first pre-placement position to each other in a plan view, and control an operation of each of the arm support unit, the arm unit, and the holding unit such that, when transferring the substrate between a second placement position set on the second placement portion and a second pre-placement position set opposite to the second placement portion, the holding unit is moved while maintaining a posture of the holding unit that holds a posture of the substrate in the predetermined direction along a center line connecting the second placement position and the second pre-placement position to each other in a plan view.

The substrate transport system according to the present invention may further include a robot control unit for controlling a transport operation of the substrate by the transfer robot. The robot control unit may control an operation of each of the turning support unit, the arm support unit, the arm unit, and the holding unit such that, when transferring the substrate between a first pre-placement position set opposite to a first placement position set on the first placement portion and a second pre-placement position set opposite to a second placement position set on the second placement portion, the holding unit is moved while maintaining a posture of the holding unit that holds a posture of the substrate in a predetermined direction along a center line connecting the first pre-placement position and the second pre-placement position to each other in a plan view, and may control the arm support unit to rotate independently relative to the turning support unit and the arm unit.

In the substrate transport system according to the present invention, the robot control unit may control operations of the turning support unit, the arm support unit, and the arm unit such that, when the holding unit moves between the first pre-placement position and the second pre-placement position, the turning support unit is rotated and moved in a first direction and the arm support unit is rotated and moved in a second direction.

The substrate transport system according to the present invention may further include a robot control unit for controlling a transport operation of the substrate by the transfer robot. The robot control unit may control an operation of each of the turning support unit, the arm support unit, the arm unit, and the holding unit such that a rotation angle of the second arm relative to the first arm in a plan view is 180 degrees or less clockwise in a plan view from a state in which the first arm and the second arm are disposed in the same direction.

According to the present invention, there is provided a transfer robot control device for controlling a transport operation of a substrate by a transfer robot that is provided inside a transport section and transports the substrate between a first placement portion and a second placement portion and includes a main body unit that is supported within the transport section, a turning support unit that is connected to the main body unit and rotates relative to the main body unit, an arm support unit that is connected to the turning support unit and rotates relative to the turning support unit, an arm unit that is connected to the arm support unit and rotates relative to the arm support unit, and a holding unit that is connected to the arm unit and holds the substrate, wherein the arm unit includes a first arm that is supported by the arm support unit, and a second arm that supports the holding unit and is supported by the first arm, wherein the turning support unit rotates using a connection portion with the main body unit as a rotation shaft in a plan view, wherein the arm support unit rotates using a connection portion with the turning support unit as a rotation shaft in a plan view, wherein the arm unit rotates using the arm support unit as a rotation shaft in a plan view, wherein the holding unit rotates relative to the second arm using a portion supported by the first arm as a rotation shaft in a plan view, wherein the arm support unit includes a turning attachment portion that is connected to the turning support unit, and an arm attachment portion to which the arm unit is connected, and wherein a center line of rotation of the arm support unit relative to the turning support unit and a center line of rotation of the arm unit relative to the arm support unit are set on the same line. The transfer robot control device includes: a storage unit; and a processing unit, wherein the processing unit includes a target position acquisition unit, a target position determination unit, and an operation control unit, wherein the storage unit stores set position information in which position information on a first placement position set on the first placement portion, position information on a first pre-placement position set at a position opposite to the first placement portion, position information on a second placement position set on the second placement portion, and position information on a second pre-placement position set at a position opposite to the second placement portion are preset, wherein the target position acquisition unit acquires position information corresponding to a movement target position of at least the holding unit that is set when the substrate is transported between the first placement portion and the second placement portion as target position information from the set position information, and sends the acquired position information to the target position determination unit, wherein the target position determination unit determines, on the basis of current position information on a current position of at least the holding unit and the target position information on the movement target position acquired by the target position acquisition unit, movement information from the current position to the movement target position of at least the holding unit, and wherein the operation control unit controls, in a case of the holding unit, the arm unit, the arm support unit, and the turning support unit, operations of rotation of the turning support unit relative to the main body unit, rotation of the arm support unit relative to the turning support unit, rotation of the arm unit relative to the arm support unit, and rotation of the holding unit relative to the arm unit.

In the transfer robot control device according to the present invention, the turning support unit may rotate using a connection portion with the main body unit as a rotation shaft in a plan view, the arm support unit may rotate using a connection portion with the turning support unit as a rotation shaft in a plan view, the arm unit may rotate in a direction opposite to that of the turning support unit using a connection portion with the arm support unit as a rotation shaft in a plan view, and the operation control unit may control a rotation direction, a rotation amount, and a rotation angle of the turning support unit and the arm unit according to the movement target position of the holding unit.

In the transfer robot control device according to the present invention, the processing unit may include an operation determination unit that determines an operation of each of the turning support unit, the arm support unit, and the arm unit to be either a linear interpolation operation in a plan view for moving one of the turning support unit, the arm support unit, and the arm unit to the movement target position or a stopping operation in accordance with a rotation operation in a plan view, and determines an operation of the holding unit to be either a linear interpolation operation in a plan view for moving the holding unit to the movement target position in accordance with a rotation operation in a plan view of each of the turning support unit, the arm support unit, and the arm unit or a stopping operation.

In the transfer robot control device according to the present invention, the operation control unit may control an operation of each of the turning support unit, the arm support unit, the arm unit, and the holding unit such that a rotation angle of the second arm relative to the first arm in a plan view is 180 degrees or less clockwise in a plan view from a state in which the first arm and the second arm are disposed in the same direction.

According to the present invention, there is provided a substrate transport system including: a transport section that defines a range within which a substrate is transported; a first placement portion and a second placement portion on which the substrate is placed; and a transfer robot that is provided inside the transport section and transports the substrate from the first placement portion to the second placement portion, wherein the transfer robot includes a main body unit that is supported within the transport section, a turning support unit that is connected to the main body unit and rotates relative to the main body unit, an arm support unit that is connected to the turning support unit and rotates relative to the turning support unit, an arm unit that is connected to the arm support unit and rotates relative to the arm support unit, and a holding unit that is connected to the arm unit and holds the substrate, wherein the arm unit includes a first arm that is supported by the arm support unit, and a second arm that supports the holding unit and is supported by the first arm, wherein the turning support unit includes a first end portion rotatably connected to the main body unit, and a second end portion to which the arm support unit is rotatably connected, wherein a first shaft member to which the arm support unit is attached is disposed at the second end portion, wherein the arm support unit includes a turning attachment portion connected to the turning support unit, and an arm attachment portion to which the arm unit is connected, wherein a second shaft member to which the arm unit is attached is disposed at the arm attachment portion, and wherein a center of rotation of the first shaft member and a center of rotation of the second shaft member are set on the same line.

### Advantage of the Invention

According to the present invention, it is possible to provide a substrate transport system and a transfer robot control device that can efficiently transport a substrate.

### BRIEF DESCRIPTION OF THE DRAWINGS

FIG. 1 is a plan view showing a substrate transport system according to the present invention.

FIG. 2 is a perspective view showing a transfer robot according to the present invention.

FIG. 3 is a perspective view showing the transfer robot according to the present invention.

FIG. 4 is a block diagram of a robot control device for the transfer robot according to the present invention.

FIG. 5A is a partial plan view showing an operating procedure of the transfer robot according to the present invention.

FIG. 5B is a plan view schematically showing the operating procedure of the transfer robot according to the present invention.

FIG. 5C is a plan view schematically showing the operating procedure of the transfer robot according to the present invention.

FIG. 6A is a plan view schematically showing the operating procedure of the transfer robot according to the present invention.

FIG. 6B is a plan view schematically showing the operating procedure of the transfer robot according to the present invention.

FIG. 7A is a plan view schematically showing the operating procedure of the transfer robot according to the present invention.

FIG. 7B is a plan view schematically showing the operating procedure of the transfer robot according to the present invention.

FIG. 8A is a plan view schematically showing the operating procedure of the transfer robot according to the present invention.

FIG. 8B is a plan view schematically showing the operating procedure of the transfer robot according to the present invention.

FIG. 9 is a plan view showing the substrate transport system according to the present invention.

FIG. 10 is a flowchart showing a control method in the substrate transport system according to the present invention.

FIG. 11A is a cross-sectional view along line A-A shown in FIG. 2.

FIG. 11B is a cross-sectional view along line B-B shown in FIG. 2.

FIG. 12 is a plan view showing another form of the substrate transport system according to the present invention.

### DESCRIPTION OF THE EMBODIMENTS

An embodiment of a substrate transport system and a transfer robot control device according to the present invention will be described below.

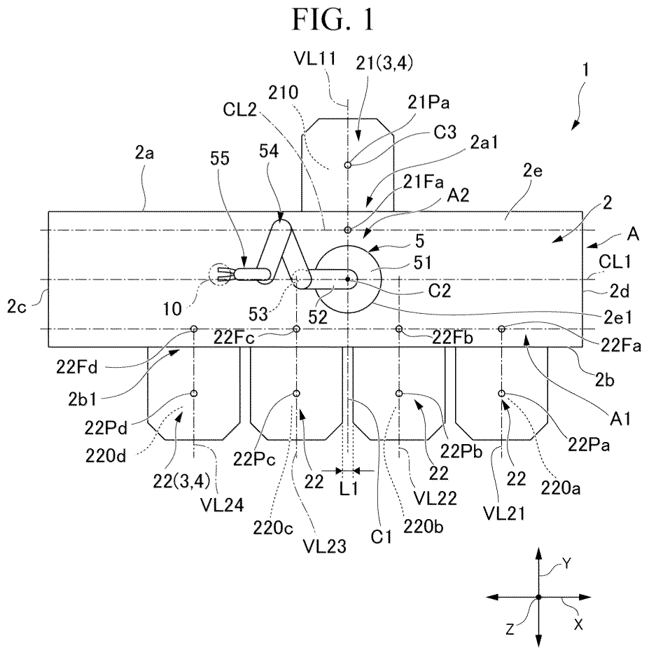

As shown in FIG. 1, the substrate transport system 1 includes a transport section 2 in which the range of a transport operation is set, a first placement portion 3, a plurality of second placement portions 4, and a transfer robot 5.

The substrate transport system 1 is a transport system that operates a transfer robot 5 to transport a substrate 10 from a first placement portion 3 to a second placement portion 4. The substrate 10 is a disk-shaped semiconductor wafer (hereinafter the “substrate 10” will be referred to as a “wafer 10”). In the wafer 10, a mark 10a (for example, an orientation flat or notch) that indicates the orientation and surface of the wafer 10 is formed.

The transport section 2 is formed, for example, in the form of a shell having a rectangular shape in a plan view. The transport section 2 defines a range within which the substrate is transported. The transport section 2 includes a first long wall 2a and a second long wall 2b disposed to face each other and extending in a first direction X, and a first short wall 2c and a second short wall 2d disposed opposite to each other and extending in a direction orthogonal to the first direction. The first long wall 2a and the second long wall 2b have a first length. The first short wall 2c and the second short wall 2d have a second length different from the first length. The transport section 2 includes, at its lower part, a lower support body 2e that is connected to the first long wall 2a, the second long wall 2b, the first short wall 2c, and the second short wall 2d. The transport section 2 includes a plurality of placement and installation portions on which the first placement portion 3 and the plurality of second placement portions 4 are installed. In the transport section 2, the first placement portion 3 is provided at the placement and installation portion provided on the first long wall 2a, and the plurality of second placement portions 4 are connected to the plurality of installation portions for placement provided on the second long wall 2b at regular intervals along the second long wall 2b. In the transport section 2, a robot support portion 2e1 for supporting the transfer robot 5 is provided on the lower support body 2e.

Hereinafter, a longitudinal direction (an extension direction of the first long wall 2a and the second long wall 2b) which is the first direction of the transport section 2 will be referred to as an X direction, a short-side direction (an extension direction of the first short wall 2c and the second short wall 2d) which is orthogonal to the first direction and is a second direction of the transport section 2 will be referred to as a Y direction, and a height direction (a vertical direction) of the transport section 2 which is orthogonal to the X direction and the Y direction will be referred to as a Z direction.

In the transport section 2, the inside of the area surrounded by the first long wall 2a, the second long wall 2b, the first short wall 2c, and the second short wall 2d is set as a movement area A which is the range of the transport operation. The transfer robot 5 is disposed inside the transport section 2, and the first placement portion 3 and the plurality of second placement portions 4 are disposed along the periphery of the transport section 2. In the movement area A, the transfer robot 5 is disposed in the central portion. In the movement area A, the area on one side in the Y direction which is bounded by the center C2 of the central portion at which the transfer robot 5 is disposed is set as a first movement area A1, and the area on the other side in the Y direction which is bounded by the center C2 of the central portion at which the transfer robot 5 is disposed is set as a second movement area A2. The first movement area A1 is an area on the side of the second long wall 2b at which the second placement portion 4 is installed. The second movement area A2 is an area on the side of the first long wall 2a at which the first placement portion 3 is provided.

Inside the transport section 2, the airflow is controlled such that the air moves from above to below, and the inside is normally kept in a positive pressure state. In the transport section 2, a load port 21 serving as the first placement portion 3 is connected to the first long wall 2a, and a plurality of treatment ports 22 serving as the plurality of second placement portions 4 are connected to the second long wall 2b. The plurality of treatment ports 22 are connected to the second long wall 2b at regular intervals in the longitudinal direction. The transport section 2 keeps the inside clean by maintaining the internal air pressure at a positive pressure and controlling the air flow from above to below.

The load port 21 is a port for supplying and recovering the wafer 10, and the plurality of treatment ports 22 are ports used for relaying between treatment steps for performing various types of semiconductor surface treatment such as film formation treatment for the wafer 10. The wafer 10 is transported from the load port 21 to the treatment port 22 by the transfer robot 5. In this case, the load port 21 corresponds to the first placement portion 3, and the treatment port 22 corresponds to the second placement portion 4. The wafer 10 that has been subjected to the surface treatment is placed in the treatment port 22 and then transported again from the treatment port 22 to the load port 21 by the transfer robot 5, where it is replaced with the next wafer 10 to be subjected to the surface treatment. In this case, the treatment port 22 corresponds to the first placement portion 3, and the load port 21 corresponds to the second placement portion 4. A container in which a plurality of wafers 10 are accommodated is placed in the load port 21, and the wafers 10 are sequentially transported to the treatment port 22 by the transfer robot 5. The container can be configured such that a predetermined number of, for example, about 25, wafers 10 are stacked at predetermined intervals in the Z direction. The load port 21 and the treatment port 22 are provided with entrance and exit portions through which the wafers 10 enter and exit from the inside of the transport section 2. The entrance and exit portions of the plurality of treatment ports 22 for the wafers 10 are formed to be aligned in the same direction.

The load port 21 is connected to a placement and installation portion 2al for the load port which is provided in the central portion of the first long wall 2a in the X direction. In the illustrated example, four treatment ports 22 (four ports) are provided at equal intervals in the X direction and are connected to a placement and installation portion 2b1 for the treatment port which is provided in the second long wall 2b. The plurality of treatment ports 22 are disposed such that the center C1 of an interval L1 between two treatment ports 22 and 22 in the X direction which are disposed in the center in the X direction approximately coincides with the central portion of the first long wall 2a in the X direction.

The transfer robot 5 is provided inside the transport section 2 and transports the wafer 10 between the load port 21 and the plurality of treatment ports 22. The transfer robot 5 is a robot configured to place and move the wafer 10. Examples of the transport of the wafer 10 include replacement transport in which the wafer 10 is replaced between the plurality of treatment ports 22 and a sequential transport in which the wafers 10 are transported to the plurality of treatment ports 22 in a preset sequence. The transfer robot 5 is disposed midway between the first long wall 2a and the second long wall 2b in the Y direction in a plan view and is disposed between the load port 21 and the plurality of treatment ports 22 in a plan view. In other words, the transfer robot 5 is disposed between the load port 21 and the plurality of treatment ports 22 in a plan view. The load port 21 and the plurality of treatment ports 22 are opposite to each other with the transfer robot 5 interposed therebetween in a plan view.

In a case in which the center of the transfer robot 5 in a plan view is defined as a center C2, the center of the load port 21 in a plan view is defined as a center C3, and the center of the interval L1 between the two treatment ports 22 and 22 in the X direction which are disposed in the center in the X direction is defined as a center C1, the transfer robot 5, the load port 21, and the treatment port 22 are disposed such that the positions of the centers C1 to C3 in the X direction approximately coincide with each other on a line extending in the Y direction. In a case in which the number of the load ports 21 and the treatment ports 22 installed is odd, the center of the port located in the center in the X direction in a plan view is defined as the center C3. In a case in which the number of the load ports 21 and the treatment ports 22 installed is even, the center of the interval in the X direction between the two ports located in the center in the X direction in a plan view is defined as the center C1. The center C2 of the transfer robot 5 is set as the central portion of the transport section 2 in the Y direction.

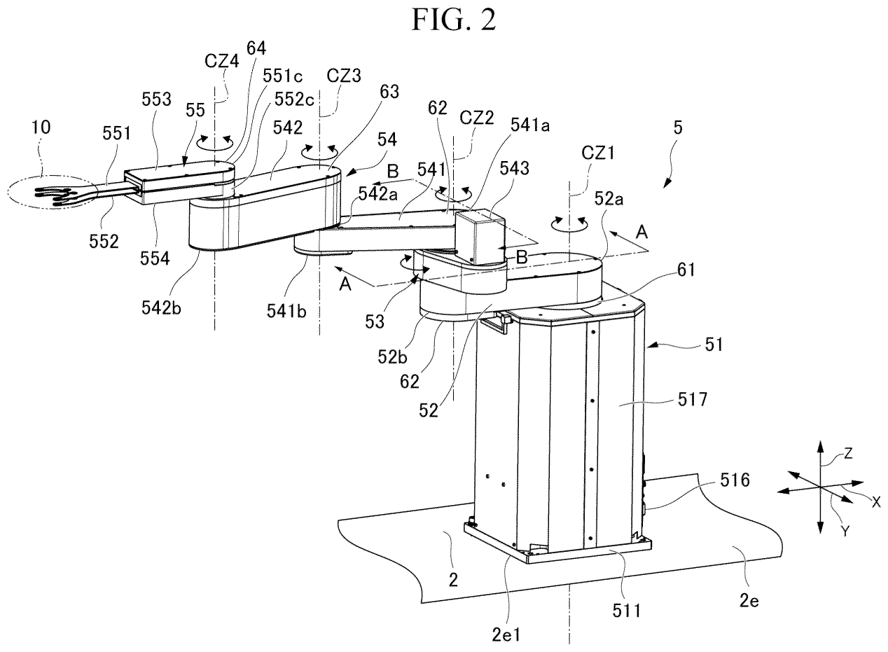

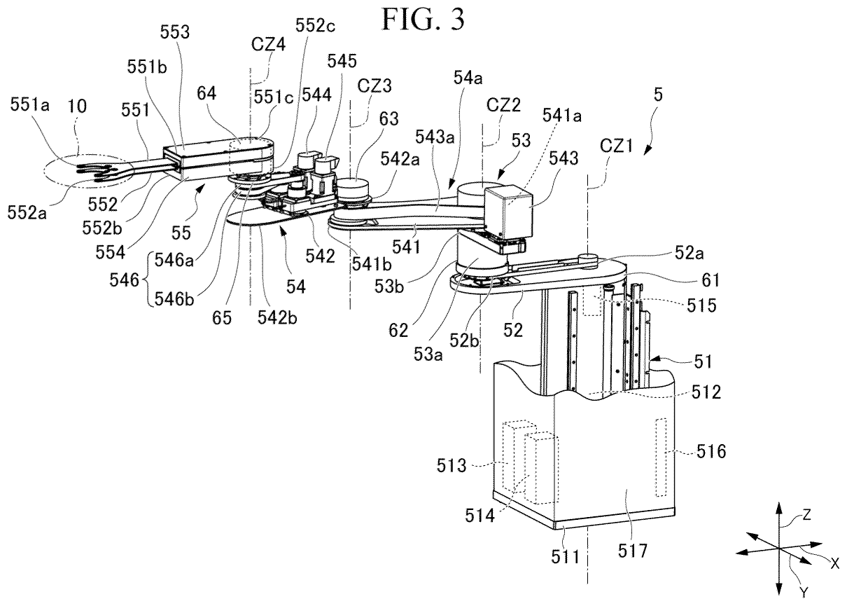

FIGS. 2 and 3 are perspective views of the transfer robot 5. FIG. 3 illustrates the transfer robot 5 with a portion thereof omitted. As shown in FIGS. 2 and 3, the transfer robot 5 includes a main body unit 51, a turning support unit 52, an arm support unit 53, an arm unit 54, and a holding unit 55.

As shown in FIG. 3, the main body unit 51 includes a base 511, a lifting portion 512, a lifting motor 513, a turning motor 514, an arm support drive motor 515, a robot control device 516 (a robot control unit) (hereinafter referred to as a “control device 516”), and a storage body 517. The base 511 is fixed to the robot support portion 2e1 provided on the lower support body 2e which constitutes the bottom portion of the transport section 2. The main body unit 51 is supported within the transport section 2 via the base 511. The lifting portion 512, the lifting motor 513, the turning motor 514, and the arm support drive motor 515 are housed within the storage body 517. The control device 516 corresponds to a control unit of the transfer robot 5 and is disposed inside the storage body 517 on the base 511.

The lifting portion 512 is provided in the storage body 517 on the base 511 so as to be movable up and down. The turning support unit 52 is supported on the upper portion of the lifting portion 512 so as to be rotatable relative to the lifting portion 512. As a lifting mechanism for the lifting portion 512 using the lifting motor 513, for example, a ball screw mechanism which includes a ball screw extending in a lifting direction and a guide member (a nut) which is screwed to the ball screw, moves in the lifting direction by the operation of the ball screw, and is connected to the lifting portion 512 is employed. The lifting portion 512 moves up and down the turning support unit 52, the arm support unit 53, the arm unit 54, and the holding unit 55, which are disposed above the main body unit 51 in the Z direction, together with the main body unit 51 by rotating the ball screw using the lifting motor 513. The transfer robot 5 can change the holding height of the wafer 10 according to the arrangement height of each of the load port 21 and the plurality of treatment ports 22 by adjusting the height using the lifting portion 512. By configuring the first placement portion 3 and the second placement portion 4 to be height adjustable, the lifting portion 512 and the lifting motor 513 of the transfer robot 5 may be omitted.

The control device 516 is provided in the storage body 517 and controls the transport operation of the wafer 10 by the transfer robot 5. In the transfer robot 5, the control device 516 is disposed on the base 511 of the main body unit 51, and the control device 516 is disposed close to control instruments (for example, output instruments such as various motors or detection instruments such as sensors) provided in the transfer robot 5, and thus it is possible to shorten the length of the electrical wiring, including a control line and to improve a control speed.

The turning support unit 52 is disposed above the main body portion 51 in the Z direction. The turning support unit 52 is disposed above the main body portion 51 in the Z direction by connecting a first end portion 52a provided on one side of the turning support unit 52 to the upper end of the lifting portion 512 of the main body unit 51. The turning support unit 52 has an arm shape extending laterally, and a first end portion 52a which is one end portion of the turning support unit 52 in the longitudinal direction is connected to the upper end of the lifting portion 512 of the main body unit 51. The turning support unit 52 rotates relative to the main body unit 51 by the turning motor 514 using the first end portion 52a as a rotation shaft (hereinafter referred to as a “first rotation shaft 61”) in a plan view. The first rotation shaft 61 is centered on the same center line CZ1 as the center C2. The turning support unit 52 has the first end portion 52a corresponding to the center line CZ1 and a second end portion 52b corresponding to a center line CZ2 different from the center line CZ1. The first rotation shaft 61 is disposed in the Z direction and rotates about the center line CZ1. The turning support unit 52 rotates approximately in a horizontal direction about the center line CZ1. The main body unit 51 is disposed within the transport section 2 such that the center (the central portion) of the turning support unit 52 is at the same position as the center C2.

The arm support unit 53 includes a turning attachment portion 53a and an arm attachment portion 53b. The arm support unit 53 is disposed above the turning support unit 52 in the Z direction. The second end portion 52b is provided below the turning attachment portion 53a in the Z direction on a side opposite to the first end portion 52a of the turning support unit 52 in the longitudinal direction. The turning attachment portion 53a is connected to the second end portion 52b of the turning support unit 52. The arm attachment portion 53b is provided above the turning attachment portion 53a in the Z direction and is connected to the arm unit 54.

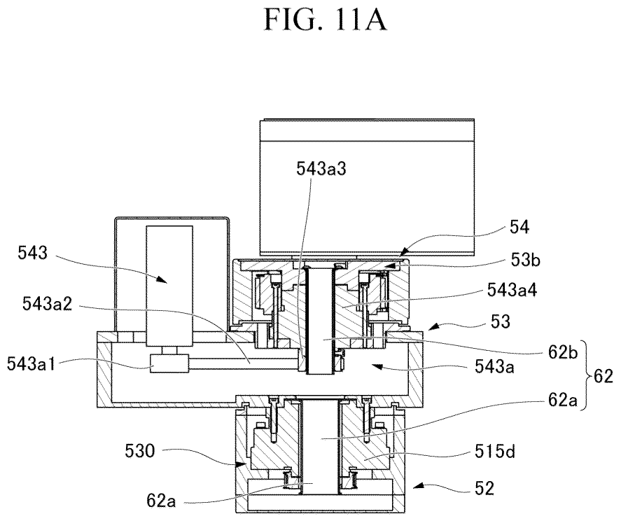

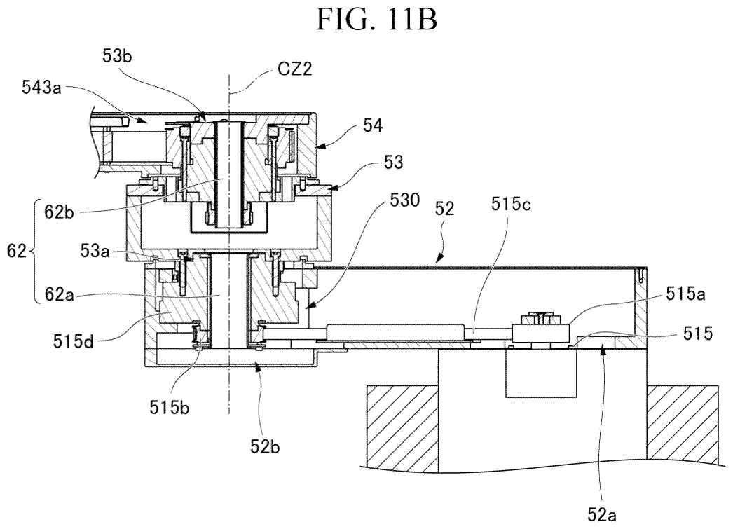

As shown in FIGS. 11A and 11B, an arm support unit rotation mechanism 530 is provided at the second end portion 52b of the turning support unit 52. The arm support unit rotation mechanism 530 includes an arm support drive motor 515, a drive pulley 515a, a transmission member 514c, a driven pulley 515b, and a rotating body 515d. The transmission member 515c transmits the rotation of the arm support drive motor 515 to the drive pulley 515a. The transmission member 515c is, for example, a steel belt. The drive pulley 515a and the driven pulley 515b are engaged with the transmission member 515c. The rotating body 515d includes the turning attachment portion 53a. The turning attachment portion 53a is connected to the driven pulley 515b, and the arm support unit 53 is attached to the turning attachment portion 53a. In addition, the arm support unit rotation mechanism 530 includes a first shaft member 62a on which the rotating body 515d and the driven pulley 515b are mounted so as to be rotatable about the center line CZ2.

The arm support unit 53 rotates relative to the turning support unit 52 by the arm support unit rotation mechanism 530 in a plan view. The rotational driving force of the arm support drive motor 515 is transmitted to the rotating body 515d via the drive pulley 515a, the transmission member 515c, and the driven pulley 515b. The transmitted rotational driving force causes the rotating body 515d to rotate around the first shaft member 62a.

The center line CZ2 is set at the second end portion 52b, and the arm support unit 53 is supported by the turning support unit 52 so as to be rotatable around the center line CZ2. The arm support unit 53 is equipped with an arm motor 543. The arm motor 543 includes an arm drive mechanism 543a that operates the arm unit 54 about the center line CZ2.

The arm drive mechanism 543a includes a transmission member 543a2, a driven pulley 543a3, and a rotating body 543a4. The transmission member 543a2 transmits the rotation of the arm motor 543 to the driven pulley 543a3. The transmission member 543a2 is, for example, a steel belt. The driven pulley 543a3 is engaged with the transmission member 543a2. The rotating body 543a4 is connected to the driven pulley 543a3 and includes the arm attachment portion 53b to which the arm unit 54 is attached. In addition, the arm drive mechanism 543a includes a second shaft member 62b on which the rotating body 543a4 and the driven pulley 543a3 are mounted so as to be rotatable about the center line CZ2.

The arm unit 54 includes a first arm 541, a second arm 542, an arm operating mechanism 54a, a first holding hand motor 544, a second holding hand motor 545, and a hand drive transmission mechanism 546. The arm unit 54 is disposed above the arm support unit 53 in the Z direction. The arm operating mechanism 54a transmits the driving force of the arm motor 543 to cause the first arm 541 and the second arm 542 to perform predetermined operations.

The first arm 541 has a first end portion 541a serving as a first arm base end portion, and a second end portion 541b serving as a first arm moving end portion. The first end portion 541a is rotatably supported by the arm support unit 53 to be connected to the arm attachment portion 53b. The second end portion 541b rotatably supports the second arm 542. The first end portion 541a and the second end portion 541b are located at both ends of the first arm 541 in the longitudinal direction. The first arm 541 is supported by the arm support unit 53 by the first end portion 541a of the first arm 541 and the arm attachment portion 53b of the arm support portion 53 being connected to each other. The first arm 541 is disposed below the second arm 542. In the first arm 541, a side of the first end portion 541a is connected to the arm drive mechanism 543a.

The first arm 541 rotates relative to the turning support unit 52 according to the rotation of the turning attachment portion 53a using the first end portion 541a as a rotation shaft (hereinafter referred to as a “second rotation shaft 62”) in a plan view. In addition, the first arm 541 rotates relative to the arm support unit 53 due to the rotation operation of the arm drive mechanism 543a by the arm motor 543 using the first end portion 541a as a rotation shaft (hereinafter referred to as a “second rotation shaft 62”) in a plan view. The second rotation shaft 62 is centered on a center line CZ2 different from the center line CZ1. The center line CZ2 is a line in the Z direction and is parallel to the center line CZ1. The first arm 541 rotates around the second rotation shaft 62 at the first end portion 541a, centered on the center line CZ2. The center line CZ2 of the rotation of the arm support unit 53 relative to the turning support unit 52 and the center line CZ2 of the rotation of the arm unit 54 relative to the arm support unit 53 are set on the same line.

The arm support unit 53 serves as a shaft base for the turning support unit 52 and the arm unit 54 which are positioned above and below the arm support unit 53 in the Z direction. The arm support unit 53 rotates independently relative to the turning support unit 52 and the arm unit 54. Specifically, the arm support unit 53 is rotated independently relative to the turning support unit 52 by the arm support drive motor 515. The arm unit 54 is rotated independently relative to the arm support unit 53 by the arm motor 543.

The second arm 542 has a first end portion 542a serving as a second arm base end portion that is rotatably connected to the second end portion 541b serving as the first arm moving end portion, and a second end portion 542b serving as a second arm moving end portion that rotatably supports the holding unit 55. The first end portion 542a and the second end portion 542b are located at both ends of the second arm 542 in the longitudinal direction. The second arm 542 is supported by the first arm 541 by the first end portion 542a of the second end portion 542 and the second end portion 541b of the first arm 541 being connected to each other. The second arm 542 rotates relative to the first arm 541 due to the rotation operation of the arm drive mechanism 543a by the arm motor 543 using the first end portion 542a as a rotation shaft (hereinafter referred to as a “third rotation shaft 63”) in a plan view. In other words, the second arm 542 rotates relative to the first arm 541 using a portion supported by the first arm 541 as a rotation shaft in a plan view. The third rotation shaft 63 is centered on a center line CZ3 different from the center line CZ1 and the center line CZ2. The center line CZ3 is a line in the Z direction and is parallel to the center line CZ1 and the center line CZ2. The second arm 542 rotates around the third rotation shaft 63 at the first end portion 542a, centered on the center line CZ3.

The first holding hand motor 544 and the second holding hand motor 545 are housed in the second arm 542, and the hand drive transmission mechanism 546 is housed in the second arm 542 on a side of the second end portion 542b. The first holding hand motor 544 and the second holding hand motor 545 are disposed in parallel in the Y direction.

The hand drive transmission mechanism 546 includes a first hand drive transmission mechanism 546a that transmits the driving force of the first holding hand motor 544, and a second hand drive transmission mechanism 546b that transmits the driving force of the second holding hand motor 545.

The arm unit 54 transmits the driving force of the arm motor 543 via the arm drive mechanism 543a, thereby causing the first arm 541 and the second arm 542 to rotate in accordance with a predetermined operation in a plan view, thereby causing the entire arm unit 54 to bend and extend around the center line CZ3, and thus the maximum length of the arm unit 54 is adjusted. Specifically, the arm unit 54 transmits the driving force of the arm motor 543 using the arm drive mechanism 543a, thereby causing the second end portion 542b serving as the second arm moving end portion to move closer to or farther away from the first end portion 541a serving as the first arm base end portion, along a straight line connecting the center line CZ2 and the center line CZ4 to each other, and thus the length of the arm portion 54 is adjusted.

The holding unit 55 includes a first holding hand 551, a second holding hand 552, a first support portion 553, and a second support portion 554. The holding unit 55 is disposed above the arm unit 54 in the Z direction.

The first holding hand 551 and the second holding hand 552 are disposed at a fixed interval in the Z direction. The first holding hand 551 is provided above the second holding hand 552. The first holding hand 551 includes a first hand tip end portion 551a that holds the wafer 10. The second holding hand 552 includes a second hand tip end portion 552a that holds the wafer 10. The first holding hand 551 and the second holding hand 552 hold the wafer 10 at the first hand tip end portion 551a and the second hand tip end portion 552a, respectively, by means of a holding mechanism (not shown). A method of holding the wafer 10 is not limited, and for example, a configuration in which the hand is inserted below the wafer 10 and raised to place the wafer 10 thereon, and then the wafer 10 is adsorbed to the hand by negative pressure, and thus the wafer 10 is held thereon is employed.

As shown in FIG. 2, the first support portion 553 and the second support portion 554 are held by the second arm 542. The first support portion 553 includes a first hand base end portion 551c that is rotatably supported by the second arm 542. The first holding hand 551 is connected to a distal end 551b of the first support portion 553. The second support portion 554 includes a second hand base end portion 552c that is rotatably supported by the second arm 542. The second holding hand 552 is connected to a distal end 552b of the second support portion 554.

The first support portion 553 rotates relative to the second arm 542 by the first holding hand motor 544 shown in FIG. 3 in a plan view. The second support portion 554 rotates relative to the second arm 542 by the second holding hand motor 545 shown in FIG. 3 in a plan view. Hereinafter, the rotation shaft of the first support portion 553 is referred to as a fourth rotation shaft 64, and the rotation shaft of the second support portion 554 is referred to as a fifth rotation shaft 65. The center of the fourth rotation shaft 64 and the center of the fifth rotation shaft 65 coincide with a center line CZ4 that is different from the center line CZ1, the center line CZ2, and the center line CZ3. The center line CZ4 is a line in the Z direction and is parallel to the center line CZ1, the center line CZ2, and the center line CZ3. The first support portion 553 and the second support portion 554 rotate about the fourth rotation shaft 64 and the fifth rotation shaft 65 that are centered on the center line CZ4. The first support portion 553 and the second support portion 554 rotate independently of each other. For example, the first support portion 553 and the second support portion 554 rotate independently of each other in a forward or reverse direction.

In the transport system 1, placement positions are each set as the positions of the placement portions on which the wafer 10 is placed at the first placement portion 3 and the second placement portion 4, and respective pre-placement positions are set as positions in front of the placement positions which are set within the range of the transport section 2 to correspond to the respective placement positions of the first placement portion 3 and the second placement portion 4. In the load port 21 corresponding to the first placement portion 3 in the present embodiment, a placement position 21Pa is set as the position of a placement portion 210, and a pre-placement position 21Fa is set as a position in front of the placement portion 210. In addition, for the plurality of treatment ports 22 corresponding to the second placement portion 4, placement positions 22Pa to 22Pd are set as the positions of placement portions 220a to 220d corresponding to the treatment ports 22, and pre-placement positions 22Fa to 22Fd are set as positions in front of the placement portions 220a to 220d.

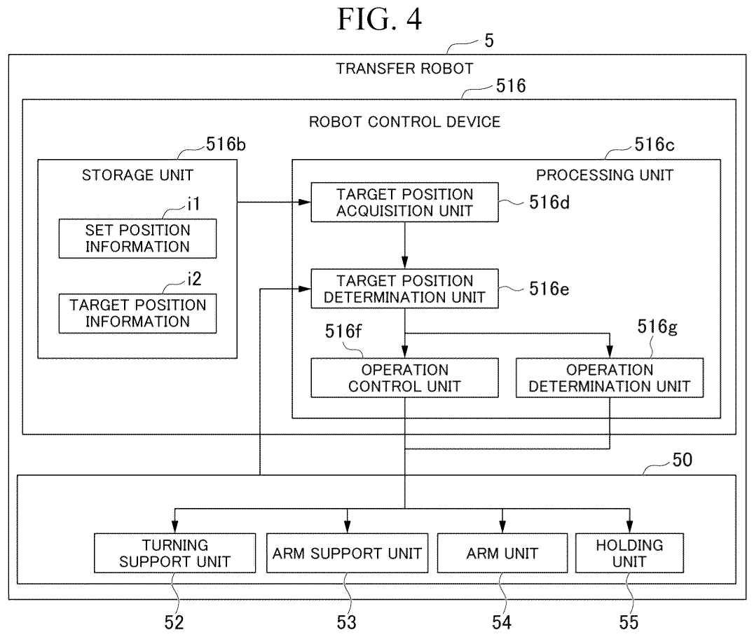

As shown in FIG. 4, the control device 516 includes a storage unit 516b and a processing unit 516c. The processing unit 516c includes a target position acquisition unit 516d, a target position determination unit 516e, an operation control unit 516f, and an operation determination unit 516g.

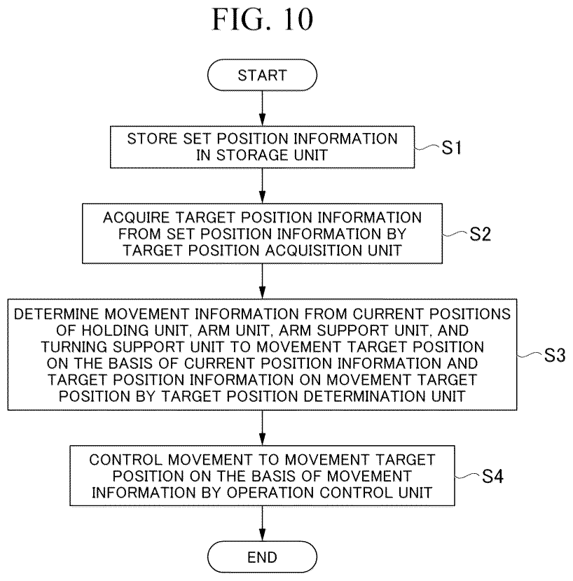

As shown in FIG. 10, in the storage unit 516b, set position information i1 in which the position information of the main body unit 51, the turning support unit 52, the arm support unit 53, the arm unit 54, and the holding unit 55 of the transfer robot 5 is preset in accordance with the position information required for the transport trajectory of the wafer 10 is stored by an input means (not shown) (S1). The set position information i1 includes the position information of the first placement portion 3 on which the wafer 10 to be transported is placed, the position information on the pre-position of the first placement portion, the position information of the second placement portion 4 to which the wafer 10 is to be transported, and the position information on the pre-position of the second placement portion. The pre-position of the first placement portion and the pre-position of the second placement portion are positions opposite to the first placement portion 3 and the second placement portion 4 in the transport section 2 in the Y direction.

The target position acquisition unit 516d acquires position information corresponding to the respective movement target positions of the turning support unit 52, the arm support unit 53, the arm unit 54, and the holding unit 55 which are set when transporting the substrate 10 from the first placement portion 3 to the second placement portion 4 as target position information i2 from the set position information i1 (S2).

The target position determination unit 516e determines movement information iM from the current positions of the turning support unit 52, the arm support unit 53, the arm unit 54, and the holding unit 55 to a movement target position P1 on the basis of current position information iR on the current positions of the turning support unit 52, the arm support unit 53, the arm unit 54, and the holding unit 55 and the target position information i2 acquired by the target position acquisition unit 516d (S3).

The operation control unit 516f controls the movement of the turning support unit 52, the arm support unit 53, the arm unit 54, and the holding unit 55 on the basis of the movement information iM determined by the target position determination unit 516e, to operate each unit of the transfer robot 5 and control each unit to move to the movement target position P1 (S4).

As shown in FIG. 4, the operation control unit 516f transmits control signals to drive sources of the turning support unit 52 and the arm unit 54, for example, and performs control to rotate the turning support unit 52 and the arm unit 54 in a plan view.

The operation determination unit 516g determines a movement method of each part of the transfer robot 5. The operation determination unit 516g determines, for example, the operation of each of the turning support unit 52 and the arm unit 54 to be any one of a rotation operation in a plan view, a linear interpolation operation in a plan view for moving one of the turning support unit 52 and the arm unit 54 to the movement target position P1 to follow the rotation operation in a plan view of the other, and a stopping operation (a fixed operation) at a disposed position. The operation determination unit 516g determines the operation of the holding unit 55 to be either a linear interpolation operation in a plan view for moving the holding unit 55 to the movement target position P1 to follow the rotation operation in a plan view of the turning support unit 52 and the arm unit 54 or a stopping operation (a fixed operation) at a disposed position.

The rotation angle of the second arm 542 relative to the first arm 541 in a plan view is 180 degrees or less clockwise in a plan view from a state in which the first arm 541 and the second arm 542 are disposed in the same direction (a state in which the arm unit 54 extends in one direction). The rotation angle of the second arm 542 in a plan view is controlled by the operation control unit 516f of the control device 516 so as to be 180 degrees or less clockwise in a plan view. The first holding hand motor 544 and the second holding hand motor 545 are housed in the second arm 542 on a side of the first end portion 542a, and the hand drive transmission mechanism 546 is housed in the second arm 542 on a side of the second end portion 542b. The first holding hand motor 544 and the second holding hand motor 545 are disposed in parallel in the Y direction.

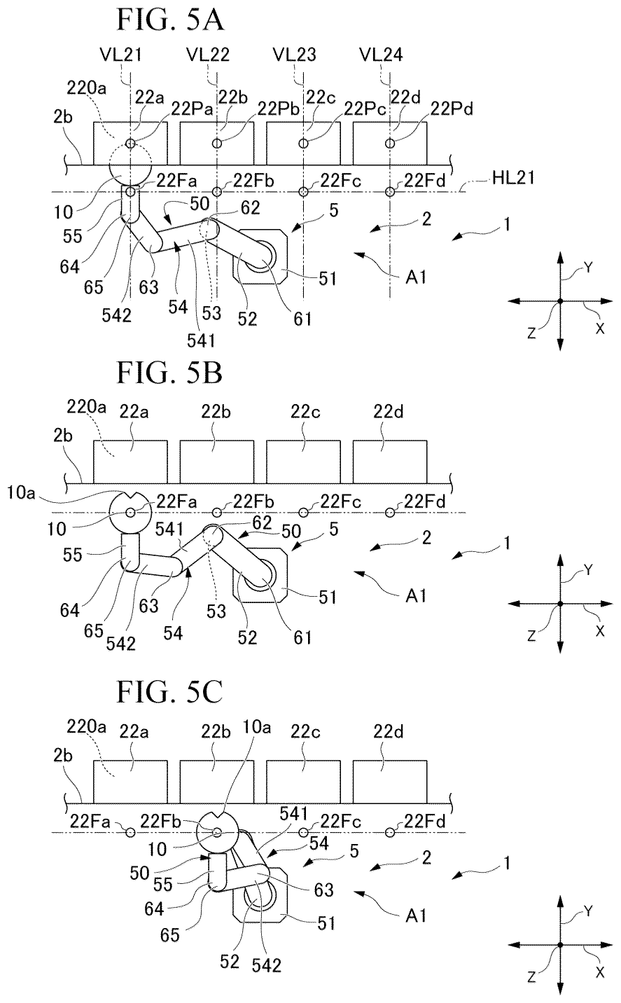

A method for transporting the wafer 10 by the transfer robot 5 in the above-described substrate transport system 1 will be described below with reference to FIGS. 5A to 8B. Hereinafter, the turning support unit 52, the arm support unit 53, the arm unit 54, and the holding unit 55 of the transfer robot 5 will be collectively referred to as an arm 50.

In the substrate transport system 1, as shown in FIG. 1, the transfer robot 5 receives the wafer 10 from the load port 21 and operates the arm 50 to transport the wafer 10 to the treatment port 22 to which the wafer 10 is to be transported. The control device 516 determines a movement target position using the target position acquisition unit 516d and a target position determination unit 516e on the basis of the set position information i1 stored in the storage unit 516b, and the movement operation of the arm 50 to the movement target position is controlled by the operation control unit 516f and the operation determination unit 516g. The wafer 10 is first transported from the placement portion 210 (the first placement portion 3) in the load port 21 to the placement portion 220a (the second placement portion 4) in a first treatment port 22a, and then transported to a surface treatment step via the first treatment port 22a. The movement of the arm 50 is controlled by the control device 516 provided in the main body unit 51.

As shown in FIG. 5A, the transfer robot 5 takes out the wafer 10 from the placement portion 220a by moving the arm support unit 53 and the arm unit 54 using the second rotation shaft 62 as a rotation shaft, moving the second arm 542 relative to the first arm 541 of the arm portion 54 using the third rotation shaft 63 as a rotation shaft, and moving the holding unit 55 using either the fourth rotation shaft 64 or the fifth rotation shaft 65 as a rotation shaft.

The transfer robot 5 takes out the wafer 10 from the placement portion 220a and rotates the turning support unit 52 and the first arm 541 in opposite directions in a plan view, respectively, using the second rotation shaft 62 and the third rotation shaft 63 as rotation shafts according to the movement direction of the holding unit 55 and the wafer 10. The first holding hand 551 is rotated in a predetermined direction using the fourth rotation shaft 64 as a rotation shaft, and the second holding hand 552 is rotated in a predetermined direction using the fifth rotation shaft 65 as a rotation shaft. Due to these rotations, a mark 10a of the wafer 10 is maintained in a predetermined orientation, and the holding unit 55 and the wafer 10 are disposed at the pre-placement position 22Fa in front of the placement portion 220a in the Y direction. Conditions such as the rotation direction, the rotation amount, and the rotation angle in the rotation operation of the turning support unit 52 and the first arm 541 in a plan view are controlled by the operation control unit 516f according to the movement target position of the holding unit 55 that holds the wafer 10. The second arm 542 rotates to follow the rotation of the first arm 541 while holding the posture of the wafer 10. In the arm 50, the rotation of the turning support unit 52 and the first arm 541 in opposite directions in a plan view causes the second end portion 542b serving as the second arm moving end portion to move closer to or farther away from the first end portion 541a serving as the first arm base end portion, along a straight line connecting the center line CZ2 and the center line CZ4 to each other, and thus the arm is bent or extended, and the arm length is adjusted.

When the arm unit 54 is bent while maintaining the posture of the left arm, the arm unit 54 rotates left (counterclockwise), and when the arm unit 54 is extended, the arm unit 54 rotates right (clockwise).

In other words, in FIGS. 5A to 5C, when the arm support unit 53 is positioned on the right side of the main body unit 51, with respect to the placement portion 220d of the treatment port 22d at a position where a distance from the arm support unit 53 is greater than the length of the turning support unit 52, when the wafer is moved from the placement position 22Pd to the pre-placement position 22Fd, the arm unit 54 rotates right (clockwise), and when the wafer is moved from the pre-placement position Fd to the placement position Pd, the arm unit 54 rotates left (counterclockwise). When the arm support unit 53 is positioned on the left side of the main body unit 51, relative to the placement portion 220a of the treatment port 22a at a position where a distance from the arm support unit 53 is greater than the length of the turning support unit 52, when the wafer is moved from the placement position 22Pa to the pre-placement position 22Fa, the arm unit 54 rotates left (counterclockwise), and when the wafer is moved from the pre-placement position 22Fa to the placement position 22Pa, the arm unit 54 rotates right (clockwise)

As shown in FIG. 5A, after the wafer 10 is disposed in front of the placement portion 220a in the Y direction, the first arm 541 is rotated clockwise in a plan view using the second rotation shaft 62 as a rotation shaft, and the second arm 542 is rotated clockwise in a plan view using the third rotation shaft 63 as a rotation shaft so as to hold the posture of the wafer 10 relative to the rotation amount of the first arm 541. By rotating the arm 50, the wafer 10 is transported from the pre-placement position 22Fa to the placement position 22Pa while holding the posture of the wafer 10, and then the wafer 10 is transported to a first surface treatment step via the first treatment port 22a.

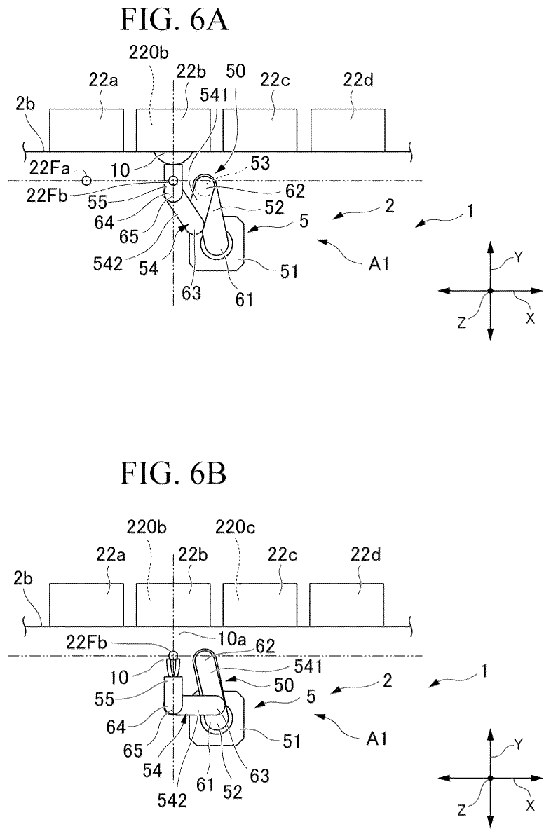

As shown in FIG. 5A, when the wafer 10 that has been subjected to the first surface treatment is placed on the placement portion 220a of the first treatment port 22a, as shown in FIG. 5B to FIG. 6A, the wafer 10 is transported from the placement portion 220a (the first placement portion 3) to the placement portion 220b (the second placement portion 4) in a second treatment port 22b. As shown in FIG. 5B, the transfer robot 5 rotates the arm support unit 53 and the arm unit 54 counterclockwise in a plan view using the second rotation shaft 62 as a rotation shaft, and rotates the second arm 542 relative to the first arm 541 of the arm portion 54 counterclockwise in a plan view using the third rotation shaft 63 as a rotation shaft. The holding unit 55 is rotated using either the fourth rotation shaft 64 or the fifth rotation shaft 65 as a rotation shaft. Due to these rotations, the wafer 10 is taken out from the placement portion 220a and transported again to the pre-placement position 22Fa, which is a position in front of the placement portion 220a in the Y direction, while the mark 10a of the wafer 10 is maintained in a predetermined orientation and the posture of the wafer 10 is held.

Under the control of the control device 516, when transporting the wafer 10 to the placement portion 220a and when taking out the wafer 10 from the placement portion 220a, the arm 50 moves the holding unit 55 along a center line VL21 (see FIG. 5A) that is parallel to the Y direction and connects the center 22Pa of the placement portion 220a in a plan view and the pre-placement position 22Fa to each other, to transport the wafer 10. Specifically, while maintaining the orientation of the mark 10a of the wafer 10 held by the holding unit 55, the holding unit 55 is moved along the center line VL21.

As shown in FIG. 5C, when transporting the wafer 10 to one side in the X direction (the first direction), the transfer robot 5 rotates the turning support unit 52 clockwise in a plan view using the first rotation shaft 61 as a rotation shaft (rotational movement), and rotates the arm support unit 53 counterclockwise in a plan view using the second rotation shaft 62 as a rotation shaft (rotational movement) to transport the wafer 10. The rotational movement means to rotate as well as to move. Alternatively, when transporting the wafer 10 to the other side in the X direction (the first direction), the transfer robot 5 rotates the turning support unit 52 counterclockwise in a plan view using the first rotation shaft 61 as a rotation shaft, and rotates the arm support unit 53 clockwise in a plan view using the second rotation shaft 62 as a rotation shaft to transport the wafer 10. By performing these transports, the wafer 10 can be transported from one pre-placement position (a first pre-placement position) of the pre-placement positions 22Fa to 22Fd to the other pre-placement position (a second pre-placement position) in a state in which the mark 10a of the wafer 10 is maintained in a predetermined orientation. For example, it is possible to move the wafer 10 from the pre-placement position 22Fa in front of the placement portion 220a in the Y direction, which is one pre-placement position of the pre-placement positions 22Fa to 22Fd, to a side of the placement portion 220b disposed in the X direction while holding the posture of the wafer 10, and to transport the wafer 10 to the pre-placement position 22Fb in front of the placement portion 220b in the Y direction in a state in which the mark 10a of the wafer 10 is maintained in a predetermined orientation.

After the wafer 10 is disposed at the pre-placement position 22Fb in front of the placement portion 220b in the Y direction, as shown in FIG. 6A, the transfer robot 5 rotates the arm support unit 53 and the arm unit 54 clockwise in a plan view using the second rotation shaft 62 as a rotation shaft, and rotates the second arm 542 relative to the first arm 541 of the arm portion 54 clockwise in a plan view using the third rotation shaft 63 as a rotation shaft. In addition, the holding unit 55 is rotated using either the fourth rotation shaft 64 or the fifth rotation shaft 65 as a rotation shaft. Due to these rotations, the wafer 10 is transported from the pre-placement position 22Fb to the placement portion 220b while the mark 10a of the wafer 10 is maintained in a predetermined orientation and the posture of the wafer 10 is held, and then the wafer 10 is transported to a second surface treatment step via the second treatment port 22b.

When the wafer 10 that has been subjected to the second surface treatment is placed on the placement portion 220b of the second treatment port 22b, as shown in FIG. 6B, the wafer 10 is transported from the placement portion 220b (the first placement portion 3) to the placement portion 220c (the second placement portion 4) in a third treatment port 22c. The transfer robot 5 rotates the arm support unit 53 and the arm unit 54 counterclockwise in a plan view using the second rotation shaft 62 as a rotation shaft, and rotates the second arm 542 relative to the first arm 541 of the arm portion 54 counterclockwise in a plan view using the third rotation shaft 63 as a rotation shaft. In addition, the holding unit 55 is rotated using either the fourth rotation shaft 64 or the fifth rotation shaft 65 as a rotation shaft. Due to these rotations, the wafer 10 is taken out from the placement portion 220b and transported again to the pre-placement position 22Fb, which is a position in front of the placement portion 220b in the Y direction, while the mark 10a of the wafer 10 is maintained in a predetermined orientation and the posture of the wafer 10 is held.

Under the control of the control device 516, when transporting the wafer 10 to the placement portion 220b and when taking out the wafer 10 from the placement portion 220b, the arm 50 moves the holding unit 55 along a center line VL22 that is parallel to the Y direction and connects the center 22Pb of the placement portion 220b in a plan view and the pre-placement position 22Fb to each other, to transport the wafer 10. Specifically, while maintaining the orientation of the mark 10a of the wafer 10 held by the holding unit 55, the holding unit 55 is moved along the center line VL22.

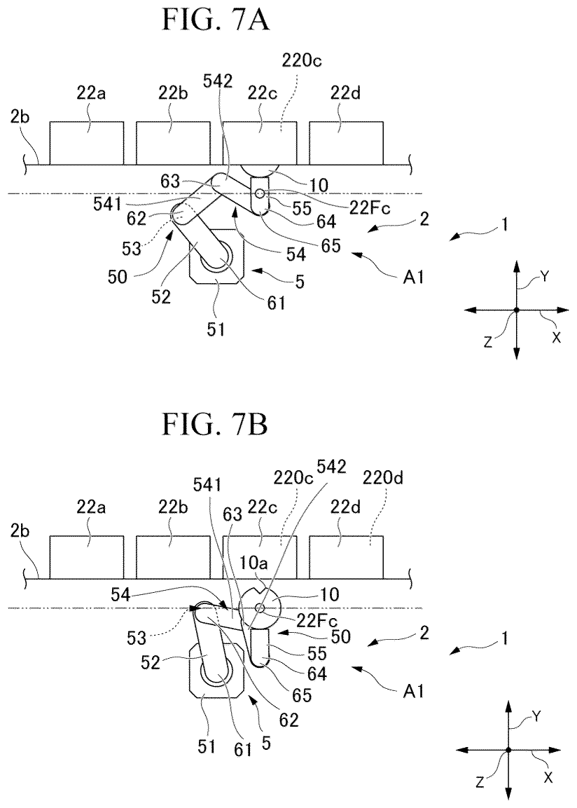

As shown in FIG. 7A, after the wafer 10 is disposed at the pre-placement position 22Fc in front of the placement portion 220c in the Y direction from the pre-placement position 22Fb, the transfer robot 5 rotates the turning support unit 52 counterclockwise in a plan view using the first rotation shaft 61 as a rotation shaft, and rotates the arm support unit 53 and the arm unit 54 counterclockwise in a plan view using the second rotation shaft 62 as a rotation shaft. In addition, the holding unit 55 is rotated using either the fourth rotation shaft 64 or the fifth rotation shaft 65 as a rotation shaft. Due to these rotations, the wafer 10 is transported to the placement portion 220c while the mark 10a of the wafer 10 is maintained in a predetermined orientation and the posture of the wafer 10 is held, and then the wafer 10 is transported to a third surface treatment step via the third treatment port 22c.

As shown in FIG. 7A, when the wafer 10 that has been subjected to the third surface treatment is placed on the placement portion 220c of the third treatment port 22c, as shown in FIG. 7B, the wafer 10 is transported from the placement portion 220c (the first placement portion 3) to the placement portion 220d (the second placement portion 4) in a fourth treatment port 22d. The transfer robot 5 rotates the turning support unit 52 clockwise in a plan view using the first rotation shaft 61 as a rotation shaft, and rotates the arm support unit 53 and the arm unit 54 clockwise in a plan view using the second rotation shaft 62 as a rotation shaft, and thus the wafer 10 is taken out from the placement portion 220c and transported again to the pre-placement position 22Fc, which is a position in front of the placement portion 220c in the Y direction, while the mark 10a of the wafer 10 is maintained in a predetermined orientation and the posture of the wafer 10 is held.

Under the control of the control device 516, when transporting the wafer 10 to the placement portion 220c and when taking out the wafer 10 from the placement portion 220c, the arm 50 moves the holding unit 55 along a center line VL23 (see FIG. 1) that is parallel to the Y direction and connects the center 22Pc of the placement portion 220c in a plan view and the pre-placement position 22Fc to each other, to transport the wafer 10. Specifically, while maintaining the orientation of the mark 10a of the wafer 10 held by the holding unit 55, the holding unit 55 is moved along the center line VL23.

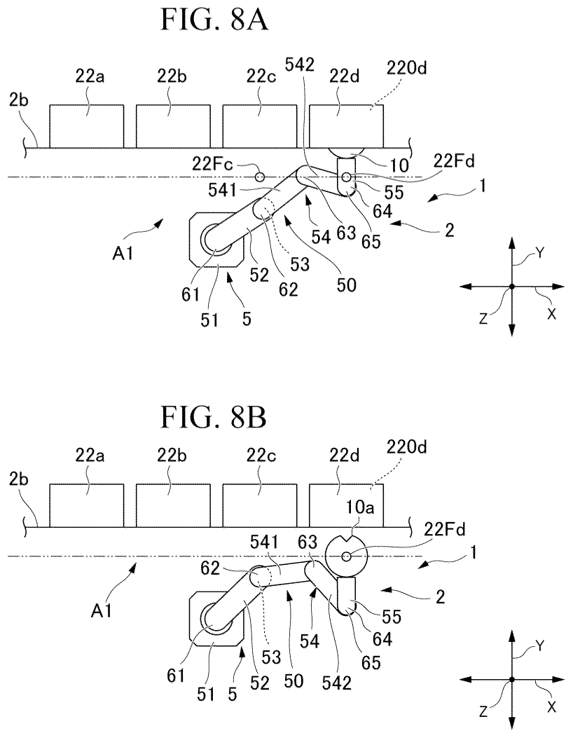

As shown in FIG. 8A, after the wafer 10 is moved to the pre-placement position 22Fd in front of the placement portion 220d in the Y direction from the pre-placement position 22Fc, the transfer robot 5 rotates the arm support unit 53 and the arm unit 54 clockwise in a plan view using the second rotation shaft 62 as a rotation shaft, and rotates the second arm 542 relative to the first arm 541 of the arm portion 54 counterclockwise in a plan view using the third rotation shaft 63 as a rotation shaft. In addition, the holding unit 55 is rotated using either the fourth rotation shaft 64 or the fifth rotation shaft 65 as a rotation shaft. Due to these rotations, the wafer 10 is transported from the pre-placement position 22Fd to the placement portion 220d while the mark 10a of the wafer 10 is maintained in a predetermined orientation and the posture of the wafer 10 is held, and then the wafer 10 is transported to a fourth surface treatment step via the fourth treatment port 22d.

As shown in FIG. 8A, when the wafer 10 that has been subjected to the fourth surface treatment is placed on the placement portion 220d of the fourth treatment port 22d, as shown in FIG. 8B, the wafer 10 is transported again from the placement portion 220d (the first placement portion 3) to the placement portion 210 (the second placement portion 4) in the load port 21. The transfer robot 5 rotates the arm support unit 53 and the arm unit 54 clockwise in a plan view using the second rotation shaft 62 as a rotation shaft, and rotates the second arm 542 relative to the first arm 541 of the arm portion 54 clockwise in a plan view using the third rotation shaft 63 as a rotation shaft. In addition, the holding unit 55 is rotated using either the fourth rotation shaft 64 or the fifth rotation shaft 65 as a rotation shaft. Due to these rotations, the wafer 10 is taken out from the placement portion 220d and transported again to the pre-placement position 22Fd in front of the placement portion 220d in the Y direction while the mark 10a of the wafer 10 is maintained in a predetermined orientation and the posture of the wafer 10 is held.

Under the control of the control device 516, when transporting the wafer 10 to the placement portion 220d and when taking out the wafer 10 from the placement portion 220d, the arm 50 moves the holding unit 55 along a center line VL24 (see FIG. 1) that is parallel to the Y direction and connects the center 22Pd of the placement portion 220d in a plan view and the pre-placement position 22Fd to each other, to transport the wafer 10. Specifically, while maintaining the orientation of the mark 10a of the wafer 10 held by the holding unit 55, the holding unit 55 is moved along the center line VL24.

After the wafer 10 is transported again to the pre-placement position 22Fd, the turning support unit 52, the first arm 541, and the second arm 542 are rotated clockwise in a plan view, and the wafer 10 that has been subjected to all the surface treatments in each treatment port 22 is transported to the placement portion 210, thereby completing the surface treatment of the wafer 10. In a case in which a plurality of wafers 10 of which each is placed on the load port 21 are housed in one container, the above-mentioned operation is repeated to sequentially perform the surface treatment on all of the wafers 10 housed in the container. After the surface treatment is completed, the wafer is taken out from the placement portion of the treatment port 22.

The rotation direction in a plan view of the turning support unit 52 and the arm unit 54 during transport to each second placement portion 4 is not limited to the above, and may be determined according to conditions such as the layout of the substrate transport system 1 and the order of transport to each placement portion. When the turning support unit 52 and the arm unit 54 rotate, the arm support unit 53 operates therebetween, and thus the orientation of the posture of the wafer 10 is always held in a predetermined orientation on one side or the other in the Y direction (the second direction).

The rotation of the arm support unit 53 and the arm unit 54 is an operation that prevents the movement direction of the wafer 10, that is, the movement trajectory of the wafer 10 supported by the holding unit 55 from deviating from the center line connecting the center of the second placement portion 4 in a plan view and the pre-placement position, which is a position in front of the second placement portion 4 in the Y direction, to each other.

When the wafer 10 is disposed at the pre-placement position in front of the second placement portion 4 in the Y direction, in a case in which the heights of the wafer 10 and the second placement portion 4 in the Z direction differ from each other, the height of the wafer 10 is adjusted by the lifting portion 512 of the main body unit 51.

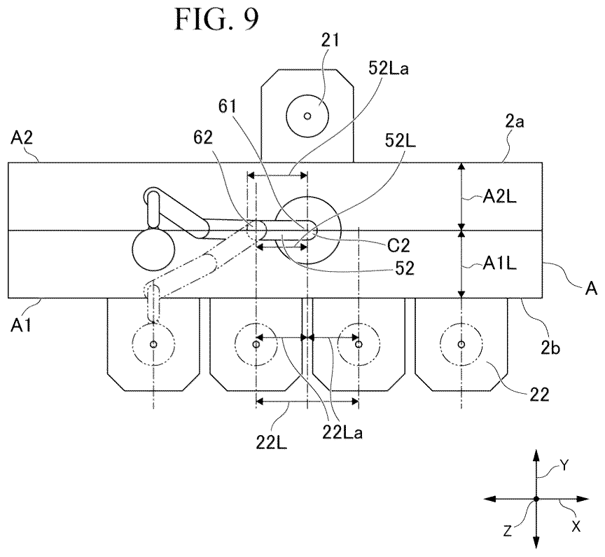

As shown in FIGS. 1 and 9, in the first movement area A1, a first area length A1L is set as the distance between the center C2 in a plan view at which the main body unit 51 of the transfer robot 5 is installed and the second long wall 2b. The first area length A1L is set to a distance equal to the length of a turning tip end length 52La, which is set as the length between the first rotation shaft 61 set at the first end portion 52a of the turning support unit 52 and an outer tip end on a side of the second end portion 52b of the turning support unit 52.

In the second movement area A2, a second area length A2L is set as the distance between the center C2 in a plan view at which the main body unit 51 of the transfer robot 5 is installed and the first long wall 2a. The second area length A2L is set to a distance equal to the length of the turning tip end length 52La, which is set as the length between the first rotation shaft 61 set at the first end portion 52a of the turning support unit 52 and an outer tip end on a side of the second end portion 52b of the turning support unit 52. In other words, the second area length A2L is set to the same distance as the first area length A1L, and the second movement area A2 equivalent to the first movement area A1 is provided.

The turning support unit 52 is connected to the main body unit 51 so as to be movable around the center C2 in a plan view, at which the main body unit 51 of the transfer robot 5 is installed, with respect to the first movement area A1 and the second movement area A2. In other words, the turning support unit 52 can freely turn within the movement area A.

A port distance 22L is set as the arrangement interval of the plurality of treatment ports 22 disposed along the second long wall 2b provided on a side of the first movement area A1 of the transport section 2. The port distance 22L is set as twice the distance of the length of an inter-turning shaft length 52L, which is set as the length between the first rotation shaft 61 set at the first end portion 52a of the turning support unit 52 and the second rotation shaft 62 set at the second end portion 52b of the turning support unit 52. In other words, the port distance is the same as the diameter of a circle having a circumferential trajectory along which the second rotation shaft 62, which is set at the second end portion 52b of the turning support unit 52 that turns around the center C2, moves.

When an odd number of treatment ports 22 are installed, the placement position of one of the treatment ports 22 on the inner side which are disposed between the other treatment ports 22 coincides with the position of a straight line passing through the center C2. The inner treatment port 22 and the other treatment ports 22 disposed on both sides are disposed at an interval equal to the port distance 22L.

When an even number of treatment ports 22 are installed, the position between two treatment ports 22 and 22 which are disposed between the other treatment ports 22 coincides with the position of a straight line passing through the center C2. The port distance 22La of the treatment ports 22 disposed on one side and the other side of the center position between the two treatment ports 22 and 22 is the same as the radius of a circle having a circumferential trajectory along which the second rotation shaft 62, which is set at the second end portion 52b of the turning support unit 52 that turns around the center C2, moves. The other treatment ports 22 disposed on outer sides of the two treatment ports 22 and 22 are disposed at an interval equal to the port distance 22L.

As described above, the positions at which the plurality of treatment ports 22 are disposed are set at intervals of an integer multiple of the port distance 22La which is set at the same distance as the inter-turning shaft length 52L around the center C2, and in a case in which an odd number of ports are disposed and in a case in which an even number of ports are disposed, the ports are disposed to be shifted by one port distance 22La. In addition, the load port 21 disposed along the first long wall 2a provided on a side of the second movement area A2 is also disposed at a position set by the port distance 22La as a position at which the treatment port 22 is disposed.

As described above, the positions and lengths of the movement area A including the first movement area A1 and the second movement area A2 provided in the substrate transport system 1, the load port 21 as the first placement portion 3 disposed around the movement area A, the plurality of treatment ports 22 as the plurality of second placement portions 4, and the inter-turning shaft length 52L and the turning tip end length 52La of the turning support unit 52 formed in the transfer robot 5 are set on the basis of the center C2. By setting in this manner, the movement of the transfer robot 5 can be performed efficiently. In addition, the wafer 10 can be transported with the mark 10a of the wafer 10 positioned in a predetermined orientation relative to the load port 21 and the plurality of treatment ports 22. In addition, the movement trajectory of the wafer 10 within the movement area A can be set to the shortest distance.

The effects of the substrate transport system and the transfer robot according to the present embodiment will be described.

The substrate transport system 1 is provided with the arm support unit 53 between the turning support unit 52 and the arm unit 54 of the arm 50 of the transfer robot 5, and thus it is possible to facilitate computational control for movement within the first movement area A1 and the second movement area A2. In addition, the arm support unit 53 is provided between the turning support unit 52 and the arm unit 54 of the arm 50 of the transfer robot 5, and thus it is possible to minimize the operation trajectory of the arm 50 during movement. As a result, it is possible to narrow the range of the movement area A1 and the movement area A2 (the length of the movement area A1 and the movement area A2 in the Y direction). For this reason, it is possible to make the transport section 2, in which the transfer robot 5 is installed, compact. The transfer robot 5 includes the arm support unit 53 between the turning support unit 52 and the arm unit 54 of the arm 50, and thus it is possible to make the movement of the arm 50 compact and to transport the wafer 10 with high efficiency.

The substrate transport system 1 is provided with the arm support unit 53 between the turning support unit 52 and the arm unit 54 of the arm 50 of the transfer robot 5. With this configuration, it is possible to transport the wafer 10 while the posture of the wafer 10 is held in a state in which the mark 10a of the wafer 10 is maintained in a predetermined orientation. For this reason, it is not necessary to adjust the orientation of the wafer 10 when loading the wafer 10 into each placement portion, and it is possible to efficiently perform the surface treatment of the wafer 10 in the treatment step connected via each treatment port 22. The transfer robot 5 includes the arm support unit 53 between the turning support unit 52 and the arm unit 54, and the operation thereof is controlled. Due to this control, it is possible to transport the wafer 10 while the orientation of the wafer 10 is aligned with that of the first placement portion 3 and the second placement portion 4, and therefore it is possible to efficiently transport the wafer 10.

In the substrate transport system 1, the transfer robot 5, the load port 21, and the plurality of treatment ports 22 are disposed such that the positions in the X direction of the center C2 of the transfer robot 5 in a plan view, the center C3 of the load port 21 in a plan view, and the center C1 of the interval L1 between the two treatment ports 22 and 22 in the X direction which are disposed in the center in the X direction approximately coincide with each other in the Y direction. With the above-mentioned configuration, the transfer robot 5 is provided with the arm support unit 53 between the turning support unit 52 and the arm unit 54 and is disposed to be centered on the center C2 in the center in a plan view within the transport section 2, and the load port 21 and the plurality of treatment ports 22 are set on the basis of the inter-turning shaft length 52L and the turning tip end length 52La of the turning support unit 52, centered on the center C2. For this reason, it is possible to shorten the movement distance of the arm 50, and it is possible to improve the efficiency of transporting the wafer 10.

The substrate transport system 1 can take out the wafer 10 from each placement portion parallel to the Y direction while maintaining the position of the mark 10a of the wafer 10 by rotating the arm 50 of the transfer robot 5. When the substrate transport system 1 moves the wafer 10 between the plurality of treatment ports 22 disposed in the X direction, it is possible to move the wafer 10 parallel to the X direction while maintaining the position of the mark 10a of the wafer 10 by rotating the arm 50. The transfer robot 5 transports the wafer 10 with linear movement while holding the posture of the wafer 10. For this reason, the transfer robot 5 can shorten the operation for aligning the orientation of the wafer 10, and can transport the wafer 10 efficiently.

The substrate transport system 1 selects the set position information i1 required for transporting the wafer 10 as the target position information i2 from the set position information i1 on each position which is stored in the storage unit 516b, by the processing of the processing unit 516c. The control device 516 determines the movement target position of each unit of the arm 50 by the target position determination unit 516e using the target position information i2, which is the target movement position of each unit of the arm 50 to be acquired by the target position acquisition unit 516d, and the current position of each unit of the arm 50. The control device 516 controls the operation of each unit of the arm 50 by the operation control unit 516f and the operation determination unit 516g in accordance with the determined movement target position of each unit of the arm 50, and transports the wafer 10.

With the above-mentioned configuration, the substrate transport system 1 can control the operation of the transfer robot 5 using the storage unit 516b and the processing unit 516c of the control device 516 such that the wafer 10 can be transported over a short movement distance while maintaining the mark 10a of the wafer 10 in a predetermined orientation. For this reason, it is possible to improve the efficiency of the transportation of the wafer 10 through the control of the operation of the transfer robot 5 by the control device 516.

The substrate transport system 1 can take out the wafer 10 from each placement portion parallel to the Y direction. For this reason, it is not necessary to form each port and each placement portion large in consideration of the range of motion of the arm 50 which is set when transporting the wafer 10, and it is possible to make each port and each placement portion small. The substrate transport system 1 is capable of moving the wafer 10 in a linear direction. For this reason, the control of the direction of the arm which is set when transporting the wafer 10 to the second placement portion 4 is not complicated, and it is possible to simplify the control of the arm.

In the arm 50 of the substrate transport system 1, the movement of the arm 50 is performed in a state in which the arm unit 54, which includes two connected arms that can be bent around the connection portion, is maintained in either a first posture in which the arm unit 54 is bent in one direction or a second posture in which the arm unit 54 is bent in the other direction. With this configuration, the arm 50 can transport the wafer 10 without changing the direction of the bending posture of the arm unit 54. For this reason, it is possible to eliminate shocks and vibrations that occur when the bending posture of the arm unit 54 is changed.

In the substrate transport system 1, the rotation angle of the second arm 542 relative to the first arm 541 in a plan view is 180 degrees or less clockwise in a plan view from a state in which the arm unit 54 extends in one direction (a state in which the first arm 541 and the second arm 542 are in a linear posture). With this configuration, by controlling the second arm 542 to be in a posture in which the second arm 542 is always bent in a transport direction relative to the first arm 541, the rotation amount of the second arm 542 can be prevented from being 180 degrees or more clockwise in a plan view. For this reason, it is possible to reduce the impact and vibration of the arm 50 that accompanies rotation that occurs when the rotation amount of the second arm 542 exceeds 180 degrees clockwise in a plan view.

The substrate transport system 1 includes one load port 21 and four treatment ports 22, but the present invention is not limited to the above configuration. The substrate transport system may be configured to include, for example, one load port 21 and three treatment ports 22. The substrate transport system may be configured to include, for example, three load ports 21 and three treatment ports 22. The substrate transport system may be configured to include, for example, a plurality of load ports 21 and one treatment port 22. The maximum number of load ports 21 and treatment ports 22 is four each. The load port 21 and the treatment port 22 are disposed such that the positions in the X direction of the center C2 of the transfer robot 5 in a plan view, the center C3 of the load port 21 in the X direction in a plan view, and the center C1 of the treatment port 22 in the X direction in a plan view approximately coincide with each other. In a case in which one of the load port 21 and the treatment port 22 is one and the other is two or more, the transfer robot 5 may be disposed so as to face one of the two or more placement portions in the Y direction.

In the substrate transport system 1, the load port 21 is disposed on a side of the first long wall 2a in the Y direction and the treatment ports 22 are disposed on a side of the second long wall 2b in the Y direction with the transfer robot 5 interposed therebetween, but the present invention is not limited to the above configuration. The substrate transport system may have a configuration in which, for example, the load ports 21 and the treatment ports 22 are disposed in parallel in either the X direction or the Y direction. In the above configuration, a plurality of transfer robots 5 may be disposed in the same direction as the arrangement direction of the load ports 21 and the treatment ports 22, and a relay portion for relaying the wafer 10 taken out from the load port 21 before the wafer 10 is transported to the treatment port 22 may be provided between the load port 21 and the treatment port 22, the transfer robot 5 on a side of the load port 21 may transport the wafer 10 to the relay portion, and the transfer robot 5 on a side of the treatment port 22 may transport the wafer 10 from the relay portion to the treatment port 22. In the case of the above configuration, the relay portion serves as the second placement portion 4 when the transported wafer 10 is temporarily placed, and serves as the first placement portion 3 when the temporarily placed wafer 10 is taken out.

A program for realizing the functions of the above-mentioned control device 516 may be recorded on a computer-readable recording medium and the program recorded on the recording medium may be read and executed by a computer system to realize the processing of the above-mentioned control device 516. Here, “the program recorded on the recording medium may be read and executed by a computer system” includes installing the program into the computer system. The term “computer system” as used herein includes an OS and hardware such as peripheral devices. The “computer system” may include a plurality of computer devices connected via a network including a communication line. The recording medium also includes an internal or external recording medium accessible from a distribution server for distributing a program.

### (Another Form of Substrate Transport System)

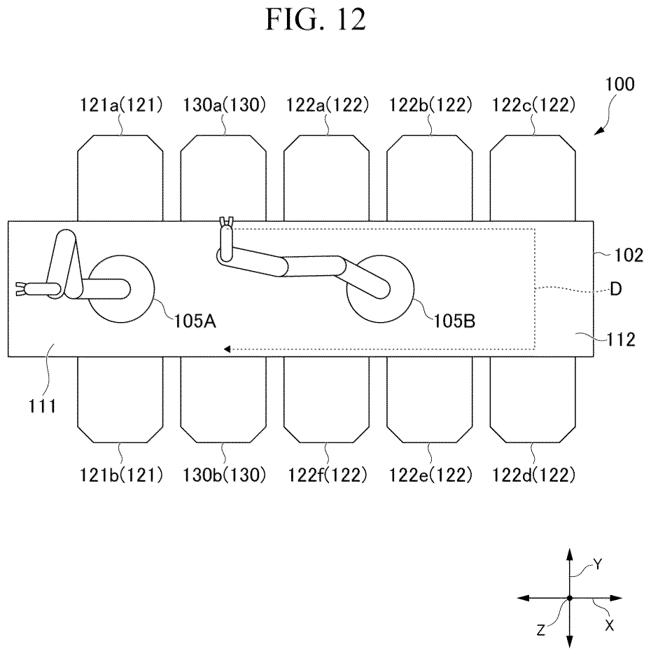

Another form of the substrate transport system of the present embodiment will be described with reference to FIG. 12. As shown in FIG. 12, a substrate transport system 100 includes two transfer robots 105A and 105B in a transport section 102.

In the transport section 102, as a transportable area, an area in which transport is possible by the first transfer robot 105A is set as a first transport section 111 and an area in which transport is possible by the second transfer robot 105B is set as a second transport section 112.

A first placement portion group 121 on which a substrate can be placed is provided around the first transport section 111, and a second placement portion group 122 on which a substrate can be placed is provided around the second transport section 112.

The transport section 102 is provided with a relay placement portion 130 for transferring the substrate between the first transfer robot 105A and the second transfer robot 105B. The relay placement portion 130 is included in the transportable area of each of the first transport section 111 and the second transport section 112, and is provided between the first placement portion group 121 and the second placement portion group 122.

For example, the substrate is transported from a relay port (not shown) to a first port 121a of the first placement portion group 121 by the first transfer robot 105A, and the substrate is subjected to a first treatment. Thereafter, the substrate is transported from the first port 121a to a second port 121b by the first transfer robot 105A, and the substrate is subjected to a second treatment.

The substrate subjected to the second treatment is transported to a first relay port 130a of the relay placement portion 130 by the first transfer robot 105A.

The substrate transported to the first relay port 130a of the relay placement portion 130 is transported to a third port 122a by the second transfer robot 105B, and the substrate is subjected to a third treatment. Thereafter, the substrate is sequentially transported from the third port 122a to a fourth port 122b and a fifth port 122c which are arranged in one direction in the transport direction by the second transfer robot 105B. The substrate transported to the fourth port 122b and the fifth port 122c is subjected to a fourth treatment in the fourth port 122b and a fifth treatment in the fifth port 122c.

The substrate subjected to the fifth treatment is transported from the fifth port 122c to a sixth port 122d by the second transfer robot 105B, and the substrate is subjected to a sixth treatment.

The substrate subjected to the sixth treatment is sequentially transported from the sixth port 122d to a seventh port 122e and an eighth port 122f which are arranged in the other direction opposite to the one direction in the transport direction by the second transfer robot 105B. The substrate transported to the seventh port 122e and the eighth port 122f is subjected to a seventh treatment in the seventh port 122e and an eighth treatment in the eighth port 122f.

The substrate subjected to the eighth treatment is transported to a second relay port 130b, and then transported to a relay port (not shown) by the first transfer robot 105A. In the transport section 102, the wafer 10 is sequentially transported from the first relay port 130a clockwise as indicated by an arrow D in FIG. 12.

The substrate transport system 100 configured in this manner also provides the same effects as those of the above embodiment. The arrangement of the transport section, the placement portion group, and the relay placement portion can be set arbitrarily, and each section or portion only has to be appropriately disposed within a range in which transport is possible by the transfer robot.

The substrate transport system 1 includes one load port 21 and four treatment ports 22, but the present invention is not limited to the above configuration. The substrate transport system 1 may be configured to include, for example, one load port 21 and three treatment ports 22. The substrate transport system 1 may be configured to include, for example, three load ports 21 and three treatment ports 22. The substrate transport system 1 may be configured to include, for example, a plurality of load ports 21 and one treatment port 22. In a case in which one of the load port 21 and the treatment port 22 is one and the other is two or more, the transfer robot 5 may be disposed so as to face one of the two or more placement portions in the Y direction.

In the substrate transport system 1, the load port 21 is disposed on a side of the first long wall 2a in the Y direction and the treatment ports 22 are disposed on a side of the second long wall 2b in the Y direction with the transfer robot 5 interposed therebetween, but the present invention is not limited to the above configuration. The substrate transport system 1 may have a configuration in which, for example, the load ports 21 and the treatment ports 22 are disposed in parallel in either the X direction or the Y direction. In the above configuration, a plurality of transfer robots 5 may be disposed in the same direction as the arrangement direction of the load ports 21 and the treatment ports 22, and a relay portion on which the wafer 10 is temporarily placed may be provided between the load port 21 and the treatment port 22 in order to relay the wafer 10 between the adjacent transfer robots 5 and 5. In the case of the above configuration, the relay portion serves as the second placement portion 4 when the transported wafer 10 is temporarily placed, and serves as the first placement portion 3 when the temporarily placed wafer 10 is taken out.

In the above, the embodiments of the present invention have been described in detail with reference to the drawings, but the specific configuration is not limited to the embodiments, and a design change not departing from the gist of the present invention is included in the present invention.

### INDUSTRIAL APPLICABILITY

It is possible to efficiently transport a substrate using a substrate transport system and a transfer robot control device.

### BRIEF DESCRIPTION OF THE REFERENCE SYMBOLS

1 Substrate transport system
2 Transport section
3 First placement portion
4 Second placement portion
5 Transfer robot
10 Substrate (wafer)
51 Main body unit
52 Turning support unit
53 Arm support unit
54 Arm unit
55 Holding unit
516 Control device (robot control unit)

1. A substrate transport system comprising:
a transport section that defines a range within which a substrate is transported;
a first placement portion and a second placement portion on which the substrate is placed; and
a transfer robot that is provided inside the transport section and transports the substrate from the first placement portion to the second placement portion,
wherein the transfer robot includes
a main body unit that is supported within the transport section,
a turning support unit that is connected to the main body unit and rotates relative to the main body unit,
an arm support unit that is connected to the turning support unit and rotates relative to the turning support unit,
an arm unit that is connected to the arm support unit and rotates relative to the arm support unit, and
a holding unit that is connected to the arm unit and holds the substrate,
wherein the arm unit includes
a first arm that is supported by the arm support unit, and
a second arm that supports the holding unit and is supported by the first arm,
wherein the turning support unit rotates using a connection portion with the main body unit as a rotation shaft in a plan view,
wherein the arm support unit rotates using a connection portion with the turning support unit as a rotation shaft in a plan view,
wherein the arm unit rotates using the arm support unit as a rotation shaft in a plan view, and
wherein the holding unit rotates relative to the second arm using a portion supported by the first arm as a rotation shaft in a plan view.

2. The substrate transport system according to claim 1, wherein the transfer robot includes
a turning motor that rotates the turning support unit relative to the main body unit,
an arm support drive motor that rotates the arm support unit relative to the turning support unit, and
an arm motor that rotates the arm unit relative to the arm support unit.

3. The substrate transport system according to claim 1, wherein the arm support unit includes an arm motor including an arm drive mechanism that operates the arm unit.

4. The substrate transport system according to claim 1,
wherein the arm support unit includes
a turning attachment portion that is connected to the turning support unit, and
an arm attachment portion to which the arm unit is connected, and
wherein a center line of rotation of the arm support unit relative to the turning support unit and a center line of rotation of the arm unit relative to the arm support unit are set on the same line.

5. The substrate transport system according to claim 1, further comprising a robot control unit for controlling a transport operation of the substrate by the transfer robot,
wherein the robot control unit
controls an operation of each of the arm support unit, the arm unit, and the holding unit such that, when transferring the substrate between a first placement position set on the first placement portion and a first pre-placement position set opposite to the first placement portion, the holding unit is moved while maintaining a posture of the holding unit that holds the substrate in a predetermined direction along a center line connecting the first placement position and the first pre-placement position to each other in a plan view, and
controls an operation of each of the arm support unit, the arm unit, and the holding unit such that, when transferring the substrate between a second placement position set on the second placement portion and a second pre-placement position set opposite to the second placement portion, the holding unit is moved while maintaining a posture of the holding unit that holds a posture of the substrate in the predetermined direction along a center line connecting the second placement position and the second pre-placement position to each other in a plan view.

6. The substrate transport system according to claim 1, further comprising a robot control unit for controlling a transport operation of the substrate by the transfer robot,
wherein the robot control unit
controls an operation of each of the turning support unit, the arm support unit, the arm unit, and the holding unit such that, when transferring the substrate between a first pre-placement position set opposite to a first placement position set on the first placement portion and a second pre-placement position set opposite to a second placement position set on the second placement portion, the holding unit is moved while maintaining a posture of the holding unit that holds a posture of the substrate in a predetermined direction along a center line connecting the first pre-placement position and the second pre-placement position to each other in a plan view, and
controls the arm support unit to rotate independently relative to the turning support unit and the arm unit.

7. The substrate transport system according to claim 6, wherein the robot control unit
controls operations of the turning support unit, the arm support unit, and the arm unit such that, when the holding unit moves between the first pre-placement position and the second pre-placement position, the turning support unit is rotated and moved in a first direction and the arm support unit is rotated and moved in a second direction.

8. The substrate transport system according to claim 1, further comprising a robot control unit for controlling a transport operation of the substrate by the transfer robot,
wherein the robot control unit
controls an operation of each of the turning support unit, the arm support unit, the arm unit, and the holding unit such that a rotation angle of the second arm relative to the first arm in a plan view is 180 degrees or less clockwise in a plan view from a state in which the first arm and the second arm are disposed in the same direction.

9. A transfer robot control device for controlling a transport operation of a substrate by a transfer robot that is provided inside a transport section and transports the substrate between a first placement portion and a second placement portion and includes
a main body unit that is supported within the transport section,
a turning support unit that is connected to the main body unit and rotates relative to the main body unit,
an arm support unit that is connected to the turning support unit and rotates relative to the turning support unit,
an arm unit that is connected to the arm support unit and rotates relative to the arm support unit, and
a holding unit that is connected to the arm unit and holds the substrate,
wherein the arm unit includes
a first arm that is supported by the arm support unit, and
a second arm that supports the holding unit and is supported by the first arm,
wherein the turning support unit rotates using a connection portion with the main body unit as a rotation shaft in a plan view,
wherein the arm support unit rotates using a connection portion with the turning support unit as a rotation shaft in a plan view,
wherein the arm unit rotates using the arm support unit as a rotation shaft in a plan view,
wherein the holding unit rotates relative to the second arm using a portion supported by the first arm as a rotation shaft in a plan view,
wherein the arm support unit includes
a turning attachment portion that is connected to the turning support unit, and
an arm attachment portion to which the arm unit is connected, and
wherein a center line of rotation of the arm support unit relative to the turning support unit and a center line of rotation of the arm unit relative to the arm support unit are set on the same line,
the transfer robot control device comprising:
a storage unit; and
a processing unit,
wherein the processing unit includes a target position acquisition unit, a target position determination unit, and an operation control unit,
wherein the storage unit stores set position information in which position information on a first placement position set on the first placement portion, position information on a first pre-placement position set at a position opposite to the first placement portion, position information on a second placement position set on the second placement portion, and position information on a second pre-placement position set at a position opposite to the second placement portion are preset,
wherein the target position acquisition unit acquires position information corresponding to a movement target position of at least the holding unit that is set when the substrate is transported between the first placement portion and the second placement portion as target position information from the set position information, and sends the acquired position information to the target position determination unit,
wherein the target position determination unit determines, on the basis of current position information on a current position of at least the holding unit and the target position information on the movement target position acquired by the target position acquisition unit, movement information from the current position to the movement target position of at least the holding unit, and
wherein the operation control unit controls, on the basis of the movement information, operations of rotation of the turning support unit relative to the main body unit, rotation of the arm support unit relative to the turning support unit, rotation of the arm unit relative to the arm support unit, and rotation of the holding unit relative to the arm unit when moving to the movement target position.

10. The transfer robot control device according to claim 9,
wherein the turning support unit rotates using a connection portion with the main body unit as a rotation shaft in a plan view,
wherein the arm support unit rotates using a connection portion with the turning support unit as a rotation shaft in a plan view,
wherein the arm unit rotates in a direction opposite to that of the turning support unit using a connection portion with the arm support unit as a rotation shaft in a plan view, and
wherein the operation control unit controls a rotation direction, a rotation amount, and a rotation angle of the turning support unit and the arm unit according to the movement target position of the holding unit.

11. The transfer robot control device according to claim 10, wherein the processing unit includes an operation determination unit that determines an operation of each of the turning support unit, the arm support unit, and the arm unit to be either a linear interpolation operation in a plan view for moving one of the turning support unit, the arm support unit, and the arm unit to the movement target position or a stopping operation in accordance with a rotation operation in a plan view, and determines an operation of the holding unit to be either a linear interpolation operation in a plan view for moving the holding unit to the movement target position in accordance with a rotation operation in a plan view of each of the turning support unit, the arm support unit, and the arm unit or a stopping operation.

12. The transfer robot control device according to claim 9, wherein the operation control unit controls an operation of each of the turning support unit, the arm support unit, the arm unit, and the holding unit such that a rotation angle of the second arm relative to the first arm in a plan view is 180 degrees or less clockwise in a plan view from a state in which the first arm and the second arm are disposed in the same direction.

13. A substrate transport system comprising:
a transport section that defines a range within which a substrate is transported;
a first placement portion and a second placement portion on which the substrate is placed; and
a transfer robot that is provided inside the transport section and transports the substrate from the first placement portion to the second placement portion,
wherein the transfer robot includes
a main body unit that is supported within the transport section,
a turning support unit that is connected to the main body unit and rotates relative to the main body unit,
an arm support unit that is connected to the turning support unit and rotates relative to the turning support unit,
an arm unit that is connected to the arm support unit and rotates relative to the arm support unit, and
a holding unit that is connected to the arm unit and holds the substrate,
wherein the arm unit includes
a first arm that is supported by the arm support unit, and
a second arm that supports the holding unit and is supported by the first arm,
wherein the turning support unit includes
a first end portion rotatably connected to the main body unit, and
a second end portion to which the arm support unit is rotatably connected,
wherein a first shaft member to which the arm support unit is attached is disposed at the second end portion,
wherein the arm support unit includes
a turning attachment portion connected to the turning support unit, and
an arm attachment portion to which the arm unit is connected,
wherein a second shaft member to which the arm unit is attached is disposed at the arm attachment portion, and
wherein a center of rotation of the first shaft member and a center of rotation of the second shaft member are set on the same line.
